(19) United States
(12) Patent Application Publication
(10) Pub. No.: US 2020/0299821 A1
(43) Pub. Date: Sep. 24, 2020

(54) VAPOR DEPOSITION MASK, METHOD FOR PRODUCING VAPOR DEPOSITION MASK, AND METHOD FOR PRODUCING ORGANIC SEMICONDUCTOR ELEMENT

(71) Applicant: HON HAI PRECISION INDUSTRY CO., LTD., New Taipei (TW)

(72) Inventors: KOSHI NISHIDA, Osaka (JP); KATSUHIKO KISHIMOTO, Osaka (JP); KOZO YANO, Osaka (JP)

(21) Appl. No.: 16/085,597

(22) PCT Filed: Jul. 22, 2016
(86) PCT No.: PCT/JP2016/071634

§ 371 Date: Sep. 17, 2018

(30) Foreign Application Priority Data
Mar. 18, 2016 (JP) 2016-055003

(51) Int. Cl. C23C 14/04; C23C 14/24; B41M 7/00; H01L 51/56; H01L 51/00

(52) U.S. Cl. CPC C23C 14/042; C23C 14/24; H01L 51/0011; H01L 51/56; H01L 51/001; B41M 7/0072

(57) ABSTRACT

A vapor deposition mask (100A) includes a base film (10A) including a plurality of first openings (13A) and containing a polymer; a composite magnetic layer (20A) formed on the base film (10A), the composite magnetic layer (20A) including a solid portion (22A) and a non-solid portion (23A); and a frame (40A) joined to a peripheral portion of the base film (10A). The plurality of first openings (13A) are formed in a region corresponding to the non-solid portion (23A); and the composite magnetic layer (20A) contains soft ferrite powder having an average particle diameter shorter than 500 nm and a resin.

### TECHNICAL FIELD

The present invention relates to a vapor deposition mask and a method for producing the vapor deposition mask, and specifically to a vapor deposition mask having a structure in which a resin layer and a metal layer are stacked on each other, a method for producing such a vapor deposition mask, and a method for producing an organic semiconductor device using such a vapor deposition mask.

### BACKGROUND ART

Recently, an organic EL (Electro-Luminescent) display device is a target of attention as a next-generation display device. In organic EL display devices currently mass-produced, an organic EL layer is formed by use of, mainly, a vacuum deposition method.

A common vapor deposition mask is a metal mask. However, it is becoming difficult to use a metal mask to form a vapor deposition pattern with high precision as organic EL display devices are becoming of a higher definition. A reason for this is that with the current metal processing technology, it is difficult to form, with high precision, small openings corresponding to a short pixel pitch (e.g., about 10 to about 20 μm) in a metal plate (thickness: e.g., about 100 μm) that is to be the metal mask.

In such a situation, a vapor deposition mask having a structure in which a resin layer and a metal layer are stacked on each other (hereinafter, referred to also as a “stack-type mask”) is proposed to be used for forming a high-definition vapor deposition pattern.

For example, Patent Document No. 1 discloses a vapor deposition mask having a structure in which a resin film and a holding member (thickness: 30 μm to 50 μm) formed of a metal magnetic material are stacked on each other. The resin film has a plurality of openings formed therein in correspondence with a desired vapor deposition pattern. The holding member has a plurality of openings formed therein larger than the openings of the resin film, so as to expose the openings of the resin film. Therefore, when the vapor deposition mask of Patent Document No. 1 is used, the vapor deposition pattern is formed in correspondence with the plurality of openings in the resin film. In a thin resin film that is thinner than a metal holding member for a common metal mask, even small openings may be formed with high precision. According to Patent Document No. 1, the holding member of the vapor deposition mask is formed of a metal magnetic material having a coefficient of thermal expansion less than 6 ppm/° C., for example, of invar.

A mask including a holding member formed of a metal magnetic material such as invar or the like is difficult to be formed to be large. For example, it is difficult to form such a mask having a side of a length exceeding 1 meter. A reason for this is that the cost for rolling performed to form a sheet of a metal magnetic material is raised.

In such a situation, Patent Document No. 2 discloses a vapor deposition mask including a magnetic layer containing magnetic powder, instead of a sheet of a metal magnetic material. The magnetic layer is formed as follows: a magnetic material-dispersed coating material containing soft magnetic material powder and additives such as a binder, a solvent, a dispersant and the like is applied to a base film and then is dried. Examples of the soft magnetic material powder may include powder of Fe, Ni, an Fe—Ni alloy, an Fe—Co alloy and an Fe—Ni—Co alloy. It is described that the soft magnetic material powder has a particle diameter of 3 μm or shorter, preferably 1 μm or shorter. As examples of the binder, siloxane polymer and polyimide are listed. The amount ratio between the soft magnetic material powder and the binder is not described. Openings in the vapor deposition mask are formed after the magnetic layer is formed on the base film.

### CITATION LIST

### Patent Literature

Patent Document No. 1: Japanese Laid-Open Patent Publication No. 2013-124372

Patent Document No. 2: Japanese Laid-Open Patent Publication No. 2014-201819

### SUMMARY OF INVENTION

### Technical Problem

However, it is difficult to stably produce a high-definition vapor deposition mask usable to produce a high-definition organic EL display device of, for example, 250 ppi or greater with the technology described in Patent Document No. 2.

The present invention made in light of the above-described situation has an object of providing a large stack-type vapor deposition mask preferably usable to form a high-definition vapor deposition pattern and a method for producing the same. Another object of the present invention is to provide a method for producing an organic semiconductor device by use of such a vapor deposition mask.

### Solution to Problem

A vapor deposition mask in an embodiment according to the present invention includes a base film including a plurality of first openings and containing a polymer; a composite magnetic layer formed on the base film, the composite magnetic layer including a solid portion and a non-solid portion; and a frame joined to a peripheral portion of the base film. The plurality of first openings are formed in a region corresponding to the non-solid portion; and the composite magnetic layer contains soft ferrite powder having an average particle diameter shorter than 500 nm and a resin.

In an embodiment, the solid portion includes a plurality of island-like portions discretely located.

In an embodiment, the plurality of island-like portions include pairs of island-like portions located in point symmetry with respect to one arbitrary first opening among the plurality of first openings as a center.

In an embodiment, the soft ferrite powder has a coercive force of 100 A/m or less.

In an embodiment, the soft ferrite powder has a Curie temperature lower than 250° C.

In an embodiment, the soft ferrite powder in the composite magnetic layer has a volume fraction of 15% by volume or higher and 80% by volume or lower.

In an embodiment, the resin includes a thermosetting resin.

In an embodiment, the base film contains polyimide, and the resin contains the same type of polyimide as that contained in the base film.

In an embodiment, the frame is formed of a nonmagnetic material. The frame is formed of, for example, a polymer material.

A method for producing the vapor deposition mask in an embodiment according to the present invention is a method for producing the vapor deposition mask in any one of the above. The method includes step A of preparing a base film containing a polymer and a frame; step B of securing the base film to the frame; step C of forming a plurality of first openings in the base film; and step D of, after the step C, forming a composite magnetic layer, containing soft ferrite powder having an average particle diameter shorter than 500 nm and a resin, on the base film. The step B includes a step of, for example, bonding the base film to the frame with, for example, an adhesive.

In an embodiment, the step B includes a step of tensioning the base film.

In an embodiment, the method further includes a step of cleaning the base film between the step C and the step D.

In an embodiment, the step D is performed by an ink jet method.

A method for producing an organic semiconductor device according to the present invention includes a step of vapor-depositing an organic semiconductor material to a work by use of the vapor deposition mask in any one of the above. The organic semiconductor device is, for example, an organic EL device.

### Advantageous Effects of Invention

An embodiment according to the present invention provides a large stack-type vapor deposition mask preferably usable to form a high-definition vapor deposition pattern and a method for producing the same. An embodiment according to the present invention provides a method for producing an organic semiconductor device by use of such a vapor deposition mask.

### BRIEF DESCRIPTION OF DRAWINGS

FIG. 1(a) is a plan view schematically showing a vapor deposition mask 100A in an embodiment according to the present invention; and FIG. 1(b) is a cross-sectional view taken along line 1B-1B′ in FIG. 1(a).

FIG. 2 is a flowchart showing a method for producing a vapor deposition mask in an embodiment according to the present invention.

FIG. 3(a) and FIG. 3(b) are respectively a plan view and a cross-sectional view showing an example of step of a method for producing the vapor deposition mask 100A; FIG. 3(b) is a cross-sectional view taken along line 3B-3B′ in FIG. 3(a).

FIG. 4(a) and FIG. 4(b) are respectively a plan view and a cross-sectional view showing an example of step of the method for producing the vapor deposition mask 100A;

FIG. 4(b) is a cross-sectional view taken along line 4B-4B′ in FIG. 4(a).

FIG. 5(a) is a plan view schematically showing another vapor deposition mask 100B in an embodiment according to the present invention; and FIG. 5(b) is a cross-sectional view taken along line 5B-5B′ in FIG. 5(a).

FIG. 6(a) is a plan view schematically showing still another vapor deposition mask 100C in an embodiment according to the present invention; and FIG. 6(b) is a cross-sectional view taken along line 6B-6B′ in FIG. 6(a).

FIG. 7(a) is a plan view schematically showing still another vapor deposition mask 100D in an embodiment according to the present invention; and FIG. 7(b) is a cross-sectional view taken along line 7B-7B′ in FIG. 7(a).

FIG. 8(a) is a plan view schematically showing still another vapor deposition mask 100E in an embodiment according to the present invention; and FIG. 8(b) is a cross-sectional view taken along line 8B-8B′ in FIG. 8(a).

FIG. 9(a) and FIG. 9(b) are respectively plan views schematically showing still other vapor deposition masks 100F and 100G in embodiments according to the present invention.

FIG. 10(a) and FIG. 10(b) are respectively plan views schematically showing still other vapor deposition masks 300A and 300B in embodiments according to the present invention.

FIG. 11(a) and FIG. 11(b) are respectively plan views schematically showing still other vapor deposition masks 300C and 300D in embodiments according to the present invention.

### DESCRIPTION OF EMBODIMENTS

A vapor deposition mask in an embodiment according to the present invention includes a base film including a plurality of first openings defining a vapor deposition region and containing a polymer, a composite magnetic layer formed on the base film, and a frame joined to a peripheral portion of the base film.

The composite magnetic layer includes a solid portion and a non-solid portion. The solid portion is a portion where a composite magnetic body is actually present, and the non-solid portion is a portion where the composite magnetic body is not present and is a portion other than the solid portion. The plurality of first openings included in the base film are formed in a region corresponding to the non-solid portion of the composite magnetic layer.

The non-solid portion includes, for example, a plurality of second openings. The plurality of first openings included in the base film are each formed in a region corresponding to any one of the plurality of second openings. The plurality of first openings and the plurality of second openings may correspond to each other on a one-to-one basis.

The solid portion includes, for example, a plurality of island-like portions discretely located. It is preferred that the plurality of island-like portions include pairs of island-like portions located in point symmetry with respect to one arbitrary first opening among the plurality of first openings as a center. It is preferred that an attraction force provided by a magnet acting on the island-like portions of the composite magnetic layer acts symmetrically on each of the first openings. A reason for this is that if the attraction force is asymmetrical, the first openings may possibly be deformed. In order to make the attraction force acting on each first opening symmetrical, a pair of (two) island-like portions located in point symmetry horizontally with respect to the center of the first opening and a pair of (two) island-like portions located in point symmetry vertically with respect to the center of the first opening are located, for example. In the case where, for example, the first opening is of a rectangle longer in a vertical direction, the distance between the pair of island-like portions located in the vertical direction is longer than the distance between the pair of island-like portions located in a horizontal direction. Instead of, or in addition to, these island-like portions, two pairs of island-like portions may be located in diagonal directions of the first opening.

The composite magnetic layer included in the vapor deposition mask in an embodiment according to the present invention contains soft ferrite powder having an average particle diameter shorter than 500 nm and a resin.

In order to, for example, form pixels of a high-definition organic EL display device of 250 ppi or greater, a vapor deposition mask having openings of, for example, about 40 μm is needed. In order to form such openings with high size precision, the restriction that the particle diameter is 1 μm or shorter as described in Patent Document No. 2 is not sufficient. It is preferred to use soft ferrite powder having an average particle diameter shorter than 500 nm, preferably 300 nm or shorter. It is preferred that the maximum diameter of the particles included in the powder is shorter than 500 nm. It is preferred that the average particle diameter of the soft ferrite powder is 10 nm or longer. There is no specific limitation on the minimum diameter of the particles included in the soft ferrite powder. It is preferred that the minimum diameter of the particles included in the soft ferrite powder is 1 nm or longer. If the particle diameter of the soft ferrite powder is too short, a problem may occur that the dispersibility of the particles is decreased or that the fluidity of the dispersion liquid used to form the composite magnetic layer is decreased. Powder having an average particle diameter shorter than 500 nm has a relatively narrow particle size distribution, although this depends on the method for production.

“Soft ferrite” refers to ferrite exhibiting soft magnetism, and contains iron oxide (Fe₂O₃ and/or Fe₃O₄) as a main component. Currently, soft ferrite is in a wide use for various applications. Main types of soft ferrite are, for example, Mn—Zn-based, Cu—Zn-based, Ni—Zn-based, and Cu—Zn—Mg-based soft ferrite. For example, Mn—Zn ferrite having a particle diameter of about 0.5 μm (500 nm) is used for a chip inductor.

The vapor deposition mask in an embodiment according to the present invention uses soft ferrite powder, whereas the vapor deposition mask described in Patent Document No. 2 uses metal powder. Soft ferrite is an oxide. Therefore, soft ferrite powder is chemically more stable than metal powder even if having an average diameter shorter than 500 nm, and thus may be handled safely. An oxide has high affinity with a resin (e.g., polyimide, epoxy resin, etc.) and is dispersed stably. Even after the resin is cured or solidified, the adhesiveness at the interface between the soft ferrite and the resin is high. The soft ferrite powder and the resin are dispersed in a solvent. The resultant dispersion liquid is applied to the base film. The solvent is removed and the resin is cured (or solidified), and as a result, the composite magnetic layer is formed. In order to improve the dispersibility of the soft ferrite powder in the dispersion liquid, a surfactant or a dispersant may be incorporated. In order to improve the adhesiveness at the interface between the soft ferrite powder and the resin in the composite magnetic layer, a silane coupling agent or the like may be incorporated. Alternatively, surfaces of the soft ferrite particles may be pre-treated (covered) with a surfactant or a silane coupling agent.

It is preferred to use soft ferrite powder having a coercive force of 100 A/m or less, and it is more preferred to use soft ferrite powder having a coercive force of 40 A/m or less. Invar, which is currently used for a composite magnetic layer, has a coercive force of about 32 A/m. The composite magnetic layer is less rigid than invar and thus is easily deformed. Namely, if the composite magnetic layer is magnetized and has residual magnetization, the composite magnetic layer and the base film may possibly be deformed by the magnetic force. In order to prevent the composite magnetic layer from being deformed by the residual magnetization, it is preferred to remove the residual magnetization from the composite magnetic layer (to demagnetize the composite magnetic layer). The demagnetization may be performed in any of various methods. For example, an alternating attenuated magnetic field may be used for the demagnetization. Alternatively, the soft ferrite powder may be heated to the Curie temperature to perform the demagnetization. Such a method of demagnetization by heating is simple. In consideration of the heat resistance of the resin contained in the base film and the composite magnetic layer, it is preferred that the soft ferrite has a Curie temperature lower than 250′C.

It is difficult to measure the physical properties such as the coercive force and the Curie temperature of the soft ferrite powder. Therefore, the physical properties of the powder are evaluated based on the physical properties of a bulk of soft ferrite having the same composition.

The resin contained in the composite magnetic layer may be a thermoplastic resin, but a thermosetting resin is preferred. The thermosetting resin is highly adhesive with the base film. The thermosetting resin is also superior to a thermoplastic resin in the heat resistance and/or the chemical stability. Examples of the thermosetting resin include an epoxy resin, polyimide, polyparaxylene, bismaleimide, silica hybrid polyimide, phenol resin, polyester resin and silicone resin. From the point of view of adhesiveness, epoxy resin and polyimide are especially preferred.

Examples of preferably usable polyimide may include thermosetting polyimide (obtained by applying a solution of polyamic acid, which is a precursor of polyimide, and heating and thus curing the polyamic acid while heating and thus removing the solvent) and soluble polyimide (obtained by applying polyimide dissolved in a solvent and heating and thus removing the solvent). In the case where the base film is formed of polyimide, it is preferred that the resin contained in the composite magnetic layer contains the same type of polyimide as that contained in the base film. In this case, the polyimide may be thermosetting or soluble. The resin contained in the composite magnetic layer and the polyimide contained in the base film may be of the same type, so that the adhesiveness between the composite magnetic layer and the base film is improved. In the case where polyimide having a small coefficient of thermal expansion (e.g., about 6 ppm/° C.) is used, the difference in the coefficient of thermal expansion between the composite magnetic layer and a work (object on which vapor deposition is to be performed; for example, glass) is made small. The difference in the coefficient of thermal expansion between the composite magnetic layer and the work may be made small, so that even if the temperature is raised during the vapor deposition, the thermal stress generated is small and thus the vapor deposition mask is suppressed from being deformed. The composite magnetic layer may include island-like portions discretely located, so that the thermal stress is decreased. Recently, a vapor deposition device utilizing a temperature rise has been developed. In order to perform vapor deposition with a high definition pattern, it is preferred to perform a preliminary experiment to form openings in consideration of the deformation caused by the heat generated at the time of the vapor deposition.

The soft ferrite powder contained in the composite magnetic layer has a volume fraction of, for example, 15% by volume or higher and 80% by volume or lower. The composite magnetic layer is provided to express an attraction force provided by the magnet, and thus it is sufficient as long as a sufficient attraction force is expressed. It is difficult to find, by calculation, the attraction force provided by the magnet. Therefore, a preliminary experiment is performed to finally determine the strength of the magnetic field generated by the magnet and the structure of the vapor deposition mask. The attraction force is influenced by the strength of the magnetic field, the magnetic permeability of soft ferrite, and the strength of the demagnetizing field associated with the thickness of the composite magnetic layer. Therefore, the parameters of the vapor deposition mask to be optimized include the thickness, the area ratio and the volume ratio of the composite magnetic layer (solid portion where the composite magnetic body is actually present) in the vapor deposition mask (region inner to the frame), and also the volume fraction of the soft ferrite powder contained in the composite magnetic layer. The magnetic field to be applied to the composite magnetic layer in order to put the vapor deposition mask into close contact with the work is, for example, 10 mT (milli-tesla) or larger and 100 mT or smaller. If the magnetic field is smaller than 10 mT, a sufficient attraction force may not be provided; whereas if the magnetic field is larger than 100 mT, dust may be attracted. Examples of usable magnet include a permanent magnet such as a rare earth magnet or the like, and an electromagnet. In the case where a permanent magnet is used, it is preferred that a plurality of permanent magnets are located in accordance with the positional arrangement of the solid portion in order to cause a uniform attraction force to act on the composite magnetic layer.

The vapor deposition mask in an embodiment according to the present invention includes the frame joined to a peripheral portion of the base film. The frame is joined to the base film without the composite magnetic layer being provided between the frame and the base film. The base film and the frame are joined together with, for example, an adhesive. It is preferred that the adhesive contains a thermosetting resin and has a heat resistance of about 250° C.

The frame does not need to be formed of a magnetic material, and may be formed of a nonmagnetic material. The frame may be formed of, for example, a resin such as ABS (acrylonitrilebutadienestyrene), PEEK (polyetheretherketone), polyimide or the like. In order to improve the mechanical properties (e.g., rigidity) of the frame, a fiber reinforced composite material (e.g., CFRP), for example, may be used. It is preferred to use CFRP containing polyimide as a matrix resin.

Hereinafter, embodiments according to the present invention will be described with reference to the drawings. The present invention is not limited to any of the following embodiments.

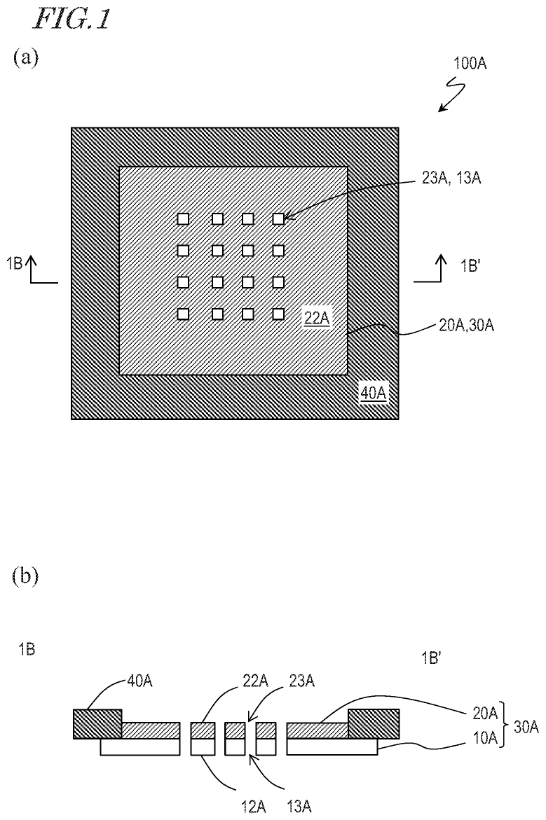

With reference to FIG. 1(a) and FIG. 1(b), a vapor deposition mask 100A in an embodiment according to the present invention will be described. FIG. 1(a) and FIG. 1(b) are respectively a plan view and a cross-sectional view schematically showing the vapor deposition mask 100A. FIG. 1(b) shows a cross-section taken along line 18-1i′ in FIG. 1(a). FIG. 1 schematically shows an example of vapor deposition mask 100A. Needless to say, none of, for example, the sizes of, the numbers of, the relative positions of, and the ratio between lengths of, the components is limited to those shown in the figures. This is applicable to the other figures referred to below.

As shown in FIG. 1(a) and FIG. 1(b), the vapor deposition mask 100A includes a base film 10A and a composite magnetic layer 20A formed on the base film 10A. Namely, the vapor deposition mask 100A has a structure in which the base film 10A and the composite magnetic layer 20A are stacked on each other. The assembly of the base film 10A and the composite magnetic layer 20A will be referred to as a “stack body 30A”.

The base film 10A contains a polymer, and is typically formed of a polymer. As the polymer, polyimide is preferred. The base film 10A may contain a polymer and a filler. The base film 10A includes a plurality of first openings 13A. A portion of the base film 10A other than the first openings 13A, namely, a portion where the base film 10A is actually present, is referred to as a “solid portion 12A”.

When the vapor deposition mask 100A is located such that the base film 10A is in close contact with a work (object on which vapor deposition is to be performed), an organic semiconductor material, for example, is vapor-deposited in a region defined by the plurality of first openings 13A. The plurality of first openings 13A, for example, are arrayed in a matrix including rows and columns. The row direction is defined as the horizontal direction and the column direction is defined as the vertical direction in this example, but these directions are not limited thereto. The plurality of first openings 13A are formed to have a size and a shape suitable to, and are located at positions suitable to, a vapor deposition pattern that is to be formed on the work. The first openings 13A are typically quadrangular, for example, rectangular, but is not limited to having such a shape and may have any shape.

The composite magnetic layer 20A is formed on the base film 10A, in a region inner to a frame 40A. The composite magnetic layer 20A includes a solid portion 22A and a non-solid portion 23A. In this example, the non-solid portion 23A includes a plurality of second openings 23A. The plurality of second openings 23A of the composite magnetic layer 20A correspond to the first openings 13A of the base film 10A on a one-to-one basis. The second openings 23A of the composite magnetic layer 20A are formed in a self-alignment manner with the first openings 13A of the base film 10A.

There is no specific limitation on the thickness of the base film 10A. It should be noted that if the base film 10A is too thick, a part of a vapor deposition film may be thinner than a desired thickness (referred to as “shadowing”). From the point of view of suppressing generation of shadowing, it is preferred that the base film 10A has a thickness of 25 μm or less. From the point of view of the strength and the resistance against washing of the base film 10A itself, it is preferred that the base film 10A has a thickness of 3 μm or greater.

As described above, the structure of the composite magnetic layer 20A is optimized together with the strength of a magnetic field generated by a magnet, such that a sufficient attraction force is provided by the magnetic field. The second openings 23A of the composite magnetic layer 20A are formed to be aligned with the first openings 13A of the base film 10A. Therefore, from the point of view of suppressing the generation of shadowing, it is preferred that a total thickness of the base film 10A and the composite magnetic layer 20A is set so as not to exceed 25 μm.

The frame 40A is joined to a peripheral portion of the base film 10A without the composite magnetic layer 20A being located between the frame 40A and the base film 10A. The base film 10A and the frame 40A are joined to each other with, for example, an adhesive (not shown). The frame 40A may be formed of a nonmagnetic material, for example, a resin.

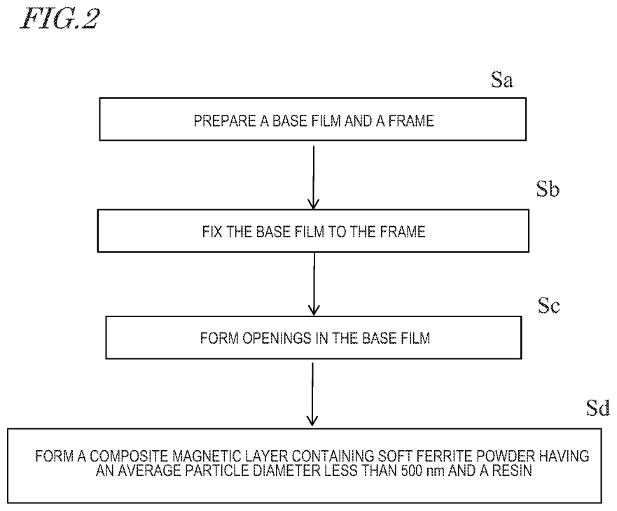

Now, with reference to FIG. 2, a method for producing a vapor deposition mask in an embodiment according to the present invention will be described. FIG. 2 is a flowchart showing the method for producing the vapor deposition mask in this embodiment according to the present invention.

First, a base film and a frame are prepared (step Sa).

Next, the base film is secured to the frame (step Sb). The base film is, for example, joined to the frame with an adhesive. In this step, the base film may be tensioned when necessary. The base film is tensioned in, for example, the horizontal direction and the vertical direction. In this embodiment according to the present invention, only the base film is tensioned. Therefore, a large tension machine as conventionally required is not required, and the frame may have a mechanical strength and a rigidity lower than those conventionally required. Thus, the frame does not need to be formed of a magnetic metal material, and may be formed of, for example, a polymer.

Next, a plurality of first openings are formed in the base film (step Sc). In this step, the base film is put into close contact with a surface of a glass substrate with a liquid being located between the base film and the glass substrate. In this state, a laser beam is radiated, so that the plurality of first openings are formed at predetermined positions with a predetermined shape and a predetermined size. It is preferred to clean the base film in order to remove debris generated as a result of laser ablation. The base film may be cleaned before a composite magnetic layer is formed, so that the composite magnetic layer and the base film are not delaminated from each other and the debris are removed with more certainty. The composite magnetic layer may possibly be delaminated especially when a surface of the base film is mechanically wiped in order to remove the debris of the film, referred to as burr, bound to perimeters of the first openings.

Next, the composite magnetic layer containing soft ferrite powder having an average particle diameter shorter than 500 nm and a resin is formed on the base film (step Sd). As described above, a dispersion liquid containing the soft ferrite powder, the resin (encompassing a precursor) and a solvent is prepared and applied to the base film. The solvent is removed and the resin is cured (solidified) to form the composite magnetic layer. The application of the dispersion liquid may be performed by, for example, a screen printing method, a slot printing method or an ink jet method. For example, the composite magnetic layer 20A of the vapor deposition mask 100A shown in FIG. 1 may be formed as follows. The concentration or the like of the dispersion liquid may be adjusted, so that the dispersion liquid is prevented by the surface tension thereof from entering the first openings 13A of the base film 10A. Thus, the composite magnetic layer having the second openings 23A formed in a self-alignment manner with the first openings 13A is formed.

As described below, in the case where a composite magnetic layer having a plurality of island-like portions located in any of various patterns is to be formed, it is preferred to use an ink jet method.

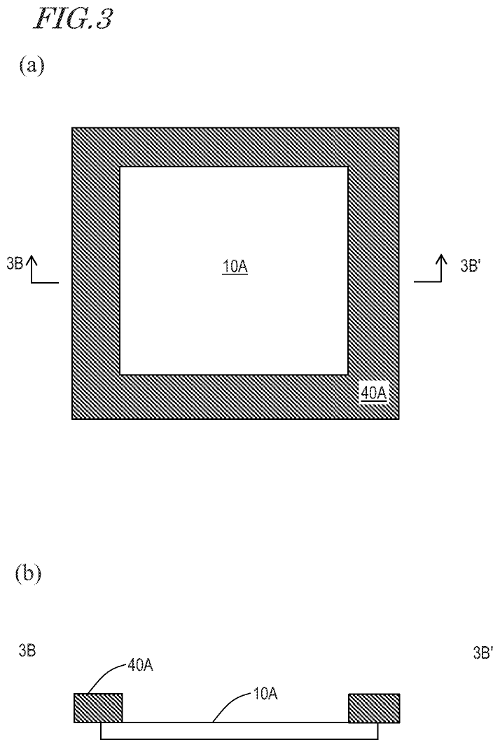

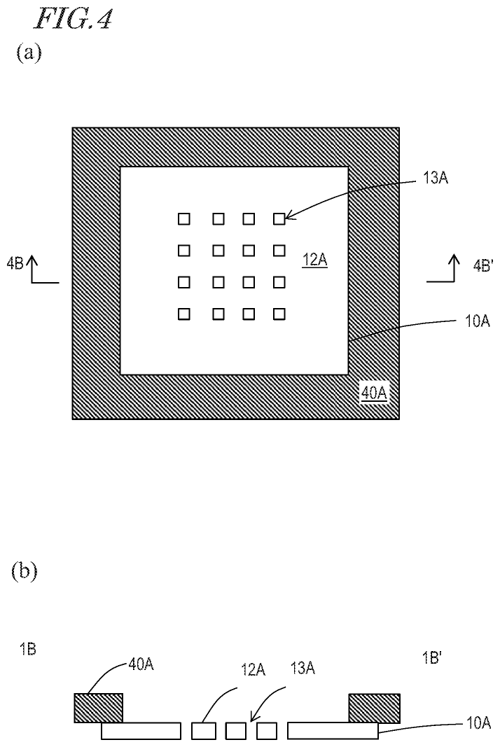

With reference to FIG. 3 and FIG. 4, the method for producing the vapor deposition mask 100A will be described. FIG. 3(a) and FIG. 3(b) are respectively a plan view and a cross-sectional view showing an example of step of a method for producing the vapor deposition mask 100A (step Sb). FIG. 4(a) and FIG. 4(b) are respectively a plan view and a cross-sectional view showing an example of step of the method for producing the vapor deposition mask 100A (step Sc).

As shown in FIG. 3(a) and FIG. 3(b), the base film 10A is secured to the frame 40A. The base film 10A is secured to the frame 40A with, for example, an adhesive (not shown). In this example, only a part of the frame 40A overlaps the base film 10A. Alternatively, the entirety of the frame 40A may overlap the base film 10A. In this step, the base film 10A may be tensioned when necessary. In order to heat and thus cure the adhesive in the state where the base film 10A is tensioned, it is preferred that the frame 40A is formed of a heat-resistant polymer material. It is preferred that the step of heating and curing the adhesive is performed at a reduced pressure in order to prevent an organic substance from being volatilized from the adhesive in the case where the vapor deposition mask 100A is used in vacuum. It is preferred that the frame 40A is formed of, for example, polyimide in order to allow the base film 10A to be tensioned while the adhesive is heated, although this depends on the heating temperature. In the case where the frame 40A needs to be rigid, CFRP of polyimide is preferably usable for the frame 40A.

In this embodiment according to the present invention, only the base film 10A is formed before the composite magnetic layer 20A is formed. Therefore, the problem that the composite magnetic layer 20A is delaminated when the base film 10A is tensioned is solved.

Next, as shown in FIG. 4(a) and FIG. 4(b), the plurality of first openings 13A are formed in the base film 10A (step Sc).

In this step, a glass substrate (not shown), for example, is located below the base film 10A (on a surface of the base film 10A opposite to a surface on which the frame 40A is located), and a liquid (e.g., ethanol) is located between the glass substrate and the base film 10A. The surface tension of the liquid is utilized to put the base film 10A into close contact with a surface of the glass substrate. In this state, a laser beam is radiated from above the base film 10A, so that the plurality of first openings 13A of a predetermined shape and a predetermined size are formed at predetermined positions.

It is preferred to clean the surface of the base film 10A after this in order to remove debris generated as a result of laser ablation. Especially in the case where burr bound to perimeters of the first openings 13A is generated on a bottom surface of the base film 10A, it is preferred to wipe the bottom surface of the base film 10A in order to remove the burr.

After this, a dispersion liquid containing soft ferrite powder, a resin (encompassing a precursor) and a solvent is applied to a top surface of the base film 10A. The solvent is removed and the resin is cured (or solidified) to form the composite magnetic layer 20A. The step of removing the solvent and heating and thus curing the resin may be formed by use of an electric furnace.

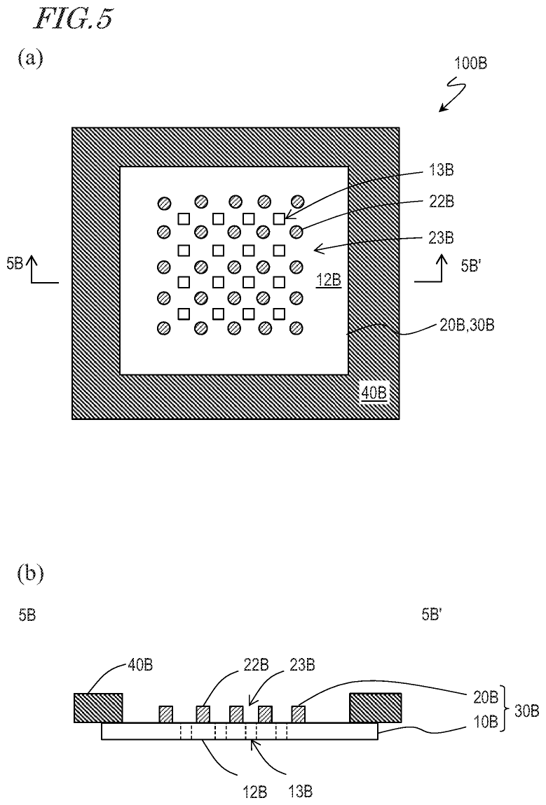

Now, with reference to FIG. 5 through FIG. 9, structures of other vapor deposition masks 100B through 100G in embodiments according to the present invention will be described. The vapor deposition masks 100B through 100G may also be produced by the method described above. It should be noted that non-solid portions 23B through 23G of composite magnetic layers 20B through 20G of the vapor deposition masks 100B through 100G are larger than first openings 13B through 13G of base films 10B through 10G. Therefore, ever, if the composite magnetic layers 20B through 20G are thicker, shadowing does not easily occur. Therefore, the composite magnetic layers 20B through 20G may be made thicker than the composite magnetic layer 20A of the vapor deposition mask 100A.

FIG. 5(a) is a plan view schematically showing one of the other vapor deposition masks in the embodiments according to the present invention, specifically, the vapor deposition mask 100B. FIG. 5(b) is a cross-sectional view taken along line 5B-5B′ in FIG. 5(a).

The vapor deposition mask 100B includes the base film 10B, the composite magnetic layer 20B (stack body 308) formed on the base film 10B, and a frame 40B joined to a peripheral portion of the base film 10B.

The base film 10B includes a solid portion 12B and the plurality of first openings 13B. The composite magnetic layer 20B includes a solid portion 22B and the non-solid portion 23B. The solid portion 22B includes a plurality of island-like portions 22B discretely located. The plurality of island-like portions 22B include two pairs of island-like portions 22B located in diagonal directions of each of the first openings 13B. Namely, four island-like portions 22B are located in the diagonal directions of each of the first openings 13B. Therefore, an attraction force provided by a magnet acting on the island-like portions 228 of the composite magnetic layer 20B acts symmetrically on each of the first openings 138.

In this example, the island-like portions 22B are circular, for example. Alternatively, the island-like portions 22B may be polygonal; or tapered, for example, conical.

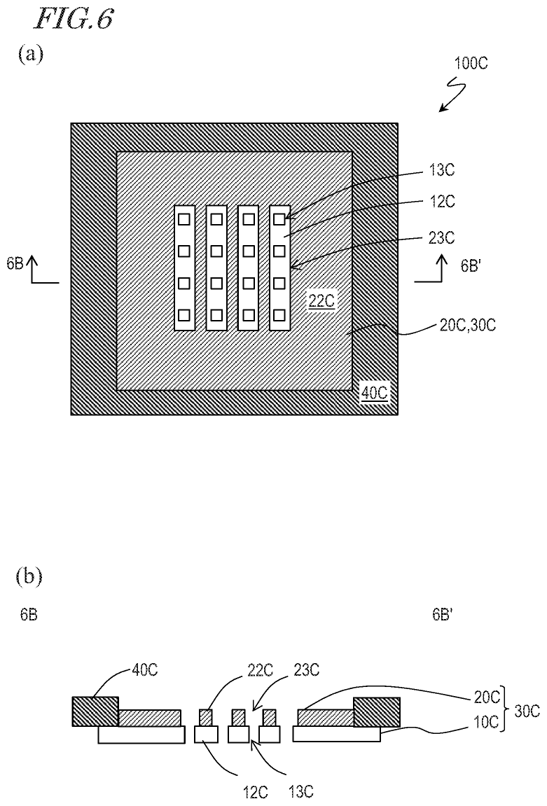

FIG. 6(a) is a plan view schematically showing another one of the other vapor deposition masks in the embodiments according to the present invention, specifically, the vapor deposition mask 100C. FIG. 6(b) is a cross-sectional view taken along line 68-6B′ in FIG. 6(a).

The vapor deposition mask 100C includes the base film 10C, the composite magnetic layer 20C (stack body 30C) formed on the base film 10C, and a frame 40C joined to a peripheral portion of the base film 10C.

The base film 10C includes a solid portion 12C and the plurality of first openings 13C. The composite magnetic layer 20C includes a solid portion 22C and the non-solid portion 23C. The non-solid portion 23C includes a plurality of slits 23C. The plurality of slits 23C, which extend in the column direction, are arrayed in the row direction. The solid portion 22C is continuously formed in a region other than the non-solid portion 23C. As seen in a direction normal to the vapor deposition mask 100C, each of the slits 23C is larger than each of the first openings 13C of the base film 10C, and two or more first openings 13C are located in each of the slits 23C (the number of the first openings 13C is not limited to the number shown in FIG. 6, needless to say).

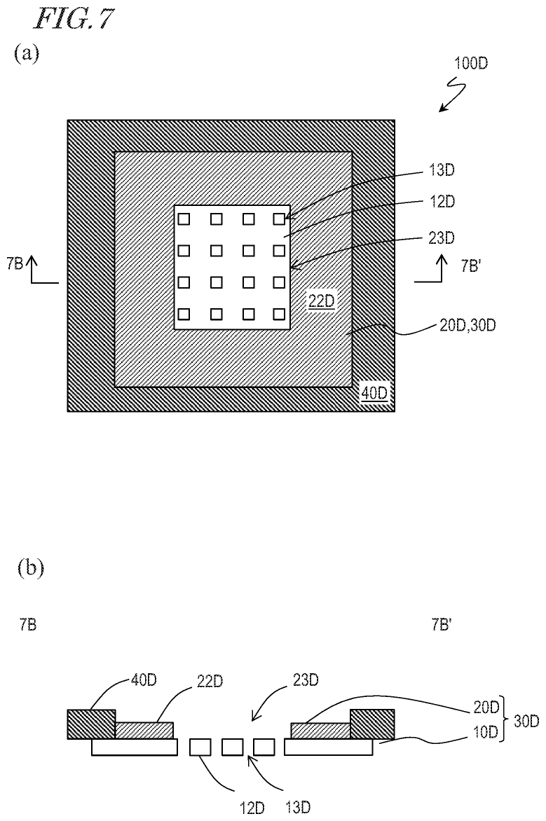

FIG. 7(a) is a plan view schematically showing still another one of the other vapor deposition masks in the embodiments according to the present invention, specifically, the vapor deposition mask 100D. FIG. 7(b) is a cross-sectional view taken along line 7B-78′ in FIG. 7(a).

The vapor deposition mask 100D includes the base film 10D, the composite magnetic layer 20D (stack body 30D) formed on the base film 10D, and a frame 40D joined to a peripheral portion of the base film 10D. The base film 10D includes a solid portion 12D and the plurality of first openings 13D. The composite magnetic layer 20D includes a solid portion 22D and the non-solid portion 23D. The non-solid portion 23D is one second opening 23D, in which all the first openings 13D are located. The solid portion 22D is continuously formed in a region other than the non-solid portion 23D.

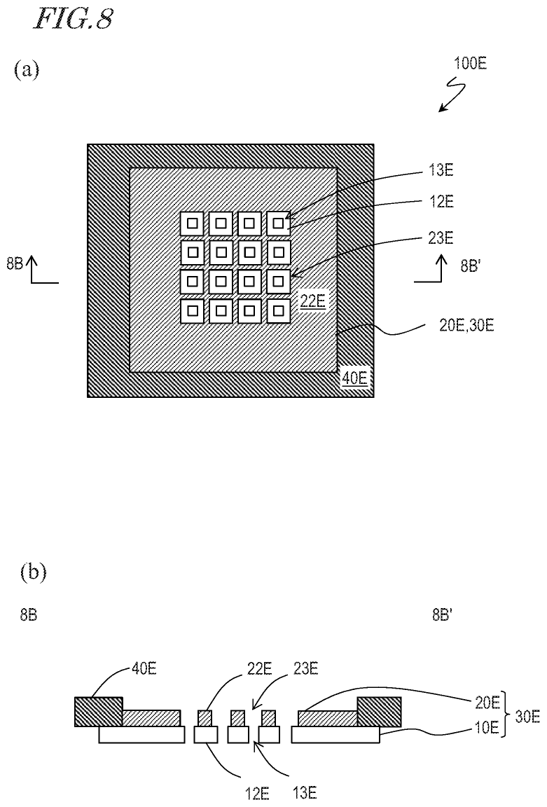

FIG. 8(a) is a plan view schematically showing still another one of the other vapor deposition masks in the embodiments according to the present invention, specifically, the vapor deposition mask 100E. FIG. 8(b) is a cross-sectional view taken along line 8B-8B′ in FIG. 8(a).

The vapor deposition mask 100E includes the base film 10E, the composite magnetic layer 20E (stack body 308) formed on the base film 10E, and a frame 40E joined to a peripheral portion of the base film 10E. The base film 101 includes a solid portion 12E and the plurality of first openings 13E. The composite magnetic layer 20E includes a solid portion 22E and the non-solid portion 23E. The non-solid portion 23E includes a plurality of second openings 23E. One first opening 131 is located in each of the second openings 238. Each of the second openings 23E is larger than each of the first openings 138. The solid portion 221 is continuously formed in a region other than the non-solid portion 23E.

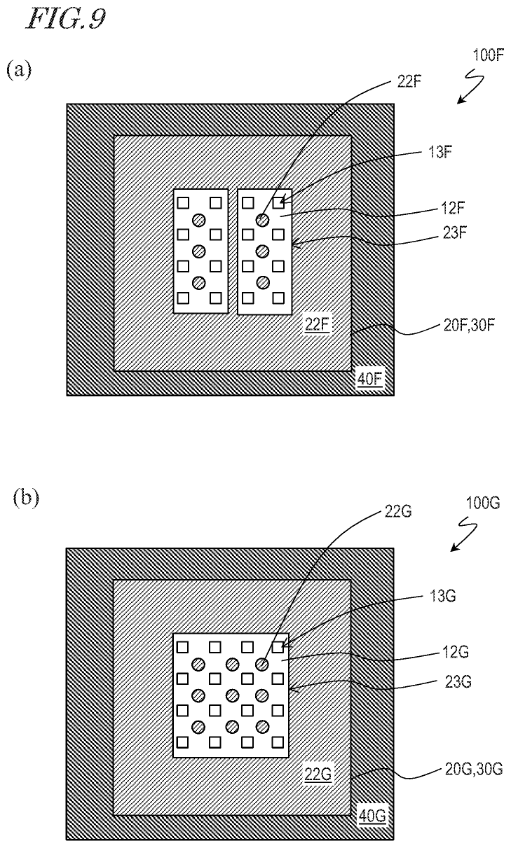

FIG. 9(a) and FIG. 9(b) are respectively plan views schematically showing still other ones of the other vapor deposition masks in the embodiments according to the present invention, specifically, the vapor deposition masks 1001 and 100G.

The vapor deposition mask 100F shown in FIG. 9(a) includes the base film 10F, the composite magnetic layer 20F (stack body 30F) formed on the base film 10F, and a frame 40F joined to a peripheral portion of the base film 10F. The base film 10F includes a solid portion 12F and the plurality of first openings 13F. The composite magnetic layer 20F includes a solid portion 22F and the non-solid portion 23F. The non-solid portion 23F includes two second openings 23F. The solid portion 221 includes a peripheral portion continuously formed around the second openings 23F and island-like portions 22F discretely located in the second openings 23F.

The vapor deposition mask 100G shown in FIG. 9(b) includes the base film 10G, the composite magnetic layer 20G (stack body 30G) formed on the base film 10G, and a frame 40G joined to a peripheral portion of the base film 10G. The base film 10G includes a solid portion 12G and the plurality of first openings 13G. The composite magnetic layer 20G includes a solid portion 22G and the non-solid portion 23G. The non-solid portion 23G is one second opening 23G, in which all the first openings 13G are located. The solid portion 22G includes a peripheral portion continuously formed around the second opening 23G and island-like portions 22G discretely located in the second opening 23G.

The vapor deposition mask in an embodiment according to the present invention may have a structure in which unit regions each corresponding to one device (e.g., organic EL display device) are located two-dimensionally. The vapor deposition mask having such a structure is preferably usable to form a plurality of devices on one substrate as an object on which vapor deposition is to be performed.

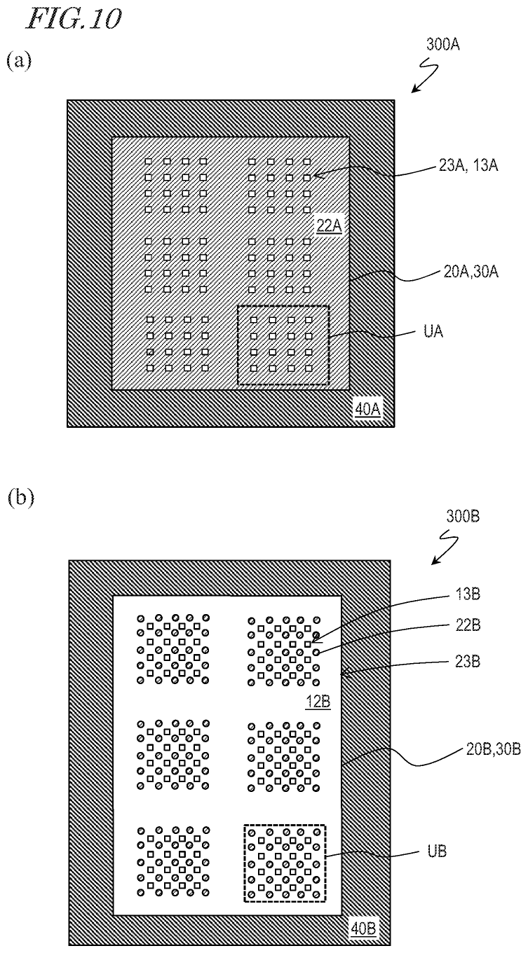

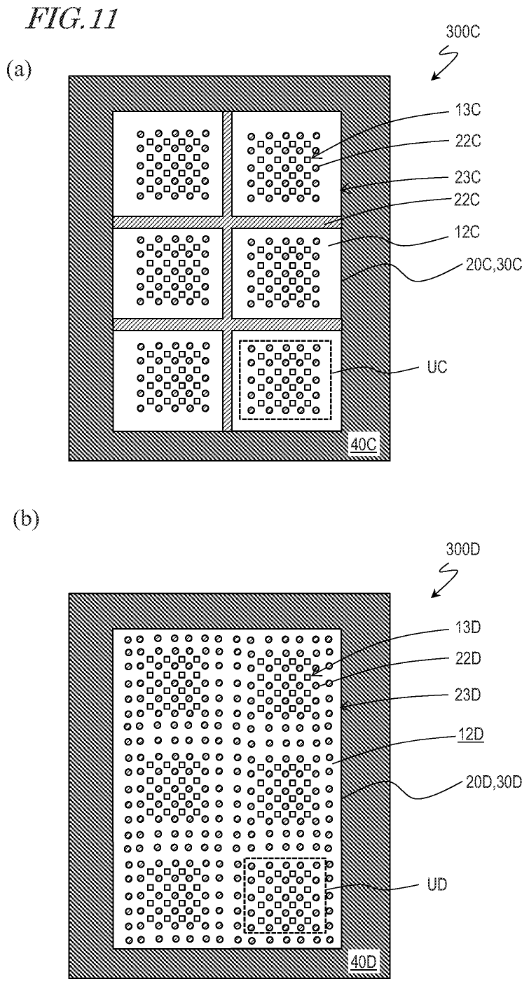

FIG. 10(a), FIG. 10(b), FIG. 11(a) and FIG. 11(b) are respectively plan views showing still other vapor deposition masks 300A, 300B, 300C and 300D in embodiments according to the present invention. These vapor deposition masks each include a plurality of (six in this example) unit regions UA through UD located at an interval as seen in a direction normal thereto. The unit regions UA of the vapor deposition mask 300A each have substantially the same pattern as that of the vapor deposition mask 100A. The unit regions UB of the vapor deposition mask 300B, the unit regions UC of the vapor deposition mask 300C, and the unit regions UD of the vapor deposition mask 300D each have substantially the same pattern as that of the vapor deposition mask 100B. The solid portion 22B of the vapor deposition mask 300B do not include a portion located between the unit regions UB. By contrast, the solid portion 22C of the composite magnetic layer 20C of the vapor deposition mask 300C includes a portion continuously formed between the unit regions UC. The solid portion 22D of the composite magnetic layer 20D of the vapor deposition mask 300D includes island-like portions 22D located between the unit regions UD.

The vapor deposition mask in an embodiment according to the present invention includes a composite magnetic layer as described above, and thus is easily made large and may be formed to have a high-definition pattern. Therefore, the vapor deposition mask is preferably usable to mass-produce, for example, a high-definition organic EL display device.

### INDUSTRIAL APPLICABILITY

A vapor deposition mask in an embodiment according to the present invention is preferably usable to produce an organic semiconductor device such as an organic EL display device, and is especially preferably usable to produce an organic semiconductor device, for which a high-definition vapor deposition pattern needs to be formed.

### REFERENCE SIGNS LIST

10A base film
12A solid portion
13A first opening (non-solid portion)
20A composite magnetic layer
22A solid portion
23A non-solid portion (second opening)
40A frame
100A vapor deposition mask
UA unit region

1. A vapor deposition mask, comprising:
a base film including a plurality of first openings and containing a polymer;
a composite magnetic layer formed on the base film, the composite magnetic layer including a solid portion and a non-solid portion; and
a frame joined to a peripheral portion of the base film;
wherein:
the plurality of first openings are formed in a region corresponding to the non-solid portion; and
the composite magnetic layer contains soft ferrite powder having an average particle diameter shorter than 500 nm and a resin.

2. The vapor deposition mask of claim 1, wherein the non-solid portion includes a plurality of second openings.

3. The vapor deposition mask of claim 1, wherein the solid portion includes a plurality of island-like portions discretely located.

4. The vapor deposition mask of claim 3, wherein the plurality of island-like portions include pairs of island-like portions located in point symmetry with respect to one arbitrary first opening among the plurality of first openings as a center.

5. The vapor deposition mask of claim 1, wherein the soft ferrite powder has a coercive force of 100 A/m or less.

6. The vapor deposition mask of claim 1, wherein the soft ferrite powder has a Curie temperature lower than 250° C.

7. The vapor deposition mask of claim 1, wherein the soft ferrite powder in the composite magnetic layer has a volume fraction of 15% by volume or higher and 80% by volume or lower.

8. The vapor deposition mask of claim 1, wherein the resin includes a thermosetting resin.

9. The vapor deposition mask of claim 1, wherein the base film contains polyimide, and the resin contains the same type of polyimide as that contained in the base film.

10. The vapor deposition mask of claim 1, wherein the frame is formed of a nonmagnetic material.

11. A method for producing the vapor deposition mask of claim 1, the method comprising:
step A of preparing a base film containing a polymer and a frame;
step B of securing the base film to the frame;
step C of forming a plurality of first openings in the base film; and
step D of, after the step C, forming a composite magnetic layer, containing soft ferrite powder having an average particle diameter shorter than 500 nm and a resin, on the base film.

12. The method for producing the vapor deposition mask of claim 11, wherein the step B includes a step of tensioning the base film.

13. The method for producing the vapor deposition mask of claim 11, further comprising a step of cleaning the base film between the step C and the step D.

14. The method for producing the vapor deposition mask of claim 11, wherein the step D is performed by an ink jet method.

15. A method for producing an organic semiconductor device, comprising a step of vapor-depositing an organic semiconductor material to a work by use of the vapor deposition mask of claim 1.
